(19) United States
(12) Patent Application Publication
(10) Pub. No.: US 2021/0291172 A1
(43) Pub. Date: Sep. 23, 2021

(54) MICROFLUIDIC DEVICES AND METHODS FOR MANUFACTURING MICROFLUIDIC DEVICES

(71) Applicant: CORNING INCORPORATED, Corning, NY (US)

(72) Inventors: Ye Fang, Painted Post, NY (US); Rui Zhang, Elmira, NY (US)

(21) Appl. No.: 17/266,236

(22) PCT Filed: Jul. 30, 2019
(86) PCT No.: PCT/US2019/044012

§ 371 Date: Feb. 5, 2021

Related U.S. Application Data
(60) Provisional application No. 62/715,004, filed on Aug. 6, 2018.

(51) Int. Cl. B01L 3/00; C03C 4/18; C03C 3/097; C03C 3/091; C03C 3/093; C03C 3/085; C03C 3/087; C03C 21/00; C03C 27/08; C03C 27/10

(52) U.S. Cl. CPC B01L 3/502707; C03C 2204/00; C03C 3/097; C03C 3/091; C03C 3/093; C03C 3/085; C03C 3/087; C03C 21/002; C03C 27/08; C03C 27/10; B01L 2300/0877; B01L 2300/0887; B01L 2300/12; B01L 2300/16; B01L 2300/0896; C03C 4/18

(57) ABSTRACT

A microfluidic device includes a flow channel disposed in a glass-based substrate; and a cover bonded to the glass-based substrate and at least partially covering the flow channel, such that the cover has a thickness of at most 200 μm.

This application claims the benefit of priority under 35 U.S.C. § 119 of U.S. Provisional Application Ser. No. 62/715,004, filed on Aug. 6, 2018, the content of which is relied upon and incorporated herein by reference in its entirety.

### BACKGROUND

### 1. Field

This disclosure relates to microfluidic devices and methods for manufacturing microfluidic devices.

### 2. Technical Background

Microfluidic devices have found wide applications in biomolecular analysis (e.g., nucleic acid sequencing, single molecule analysis, etc.) due to their ability to spatially and/or temporally control bioreactions, which is critical to many biomolecular analyses. For instance, in optical detection-based parallel gene sequencing techniques (i.e., next generation sequencing (NGS)), millions of short DNA fragments generated from a genomic DNA sample may be immobilized and partitioned onto a surface of the microfluidic device such that the DNA fragments are spatially separated from each other to facilitate sequencing by, for example, synthesis, ligation, or single-molecule real-time imaging. Glass-based microfluidic devices employing cover glasses are commonly used for optical detection-based NGS or single molecule analysis.

However, challenges exist in manufacturing microfluidics devices with thin cover glass structures. For example, the cover glass can be fragile and may be broken during handling, assembly, packing, shipping or usage. For current microfluidic devices or flow cells employing thick cover glasses (e.g., 230 μm to 700 μm), high resolution imaging is often extremely difficult.

This disclosure presents improved microfluidic devices having thin and strengthened cover glasses and methods for manufacturing thereof for biomolecular analysis, in particular gene sequencing.

### SUMMARY

In some embodiments, a microfluidic device comprises: a flow channel disposed in a glass-based substrate; and a cover bonded to the glass-based substrate and at least partially covering the flow channel, wherein the cover has a thickness of at most 200 μm.

In one aspect, which is combinable with any of the other aspects or embodiments, the microfluidic device further comprises: an inlet opening through at least one of the glass-based substrate or the cover and in fluid communication with the flow channel; and an outlet opening through at least one of the glass-based substrate or the cover and in fluid communication with the flow channel.

In one aspect, which is combinable with any of the other aspects or embodiments, a first glass-based layer defines a floor of the flow channel; a second glass-based layer defines sidewalls of the flow channel; and the cover defines a ceiling of the flow channel.

In one aspect, which is combinable with any of the other aspects or embodiments, the cover has a thickness in a range of 100 μm to 180 μm.

In one aspect, which is combinable with any of the other aspects or embodiments, the cover comprises: SiO₂ in a range of 56 mol. % to 72 mol. %; Al₂O₃ in a range of 5 mol. % to 22 mol. %; B₂O₃ in a range of 0 mol. % to 15 mol. %; Na₂O in a range of 3 mol. % to 25 mol. %; K₂O in a range of 0 mol. % to 5 mol. %; MgO in a range of 1 mol. % to 6 mol. %; SnO₂ in a range of 0 mol. % to 1 mol. %.

In one aspect, which is combinable with any of the other aspects or embodiments, the cover further comprises: Li₂O in a range of 0 mol. % to 7 mol. %; and P₂O₅ in a range of 0 mol. % to 10 mol. %.

In one aspect, which is combinable with any of the other aspects or embodiments, the cover further comprises: CaO in a range of 0 mol. % to 3 mol. %; and ZrO₂ in a range of 0 mol. % to 2 mol. %.

In one aspect, which is combinable with any of the other aspects or embodiments, the cover further comprises: ZnO in a range of 0 mol. % to 6 mol. %.

In one aspect, which is combinable with any of the other aspects or embodiments, the cover is configured to have an autofluorescence in a wavelength range of 400 nm to 750 nm of as low as the autofluorescence of pure silica substrate.

In one aspect, which is combinable with any of the other aspects or embodiments, the cover is configured to have an average surface tilt or slope of at most about 100 nm/mm, measured using a laser interferometer.

In one aspect, which is combinable with any of the other aspects or embodiments, the average surface flatness is at most about 50 nm/mm.

In one aspect, which is combinable with any of the other aspects or embodiments, the cover is configured to have a surface roughness of at most about 10 nm/um².

In one aspect, which is combinable with any of the other aspects or embodiments, the surface roughness is at most about 5 nm/um².

In one aspect, which is combinable with any of the other aspects or embodiments, the cover is bonded to the glass-based substrate at a bonded volume comprising a bonding material diffused into each of the glass-based substrate and the cover.

In one aspect, which is combinable with any of the other aspects or embodiments, the microfluidic device further comprises a bonding layer disposed between the glass-based substrate and the cover.

In one aspect, which is combinable with any of the other aspects or embodiments, the bonding layer comprises a metal.

In one aspect, which is combinable with any of the other aspects or embodiments, the metal comprises one or more of gold, chromium, titanium, nickel, copper, zinc, cerium, lead, iron, vanadium, manganese, magnesium, germanium, aluminum, tantalum, niobium, tin, indium, cobalt, tungsten, ytterbium, zirconium, or an oxide thereof, or a combination thereof.

In one aspect, which is combinable with any of the other aspects or embodiments, the bonding layer comprises a polymer-carbon black composite film.

In one aspect, which is combinable with any of the other aspects or embodiments, the microfluidic device is a flow cell for DNA sequencing.

In one aspect, which is combinable with any of the other aspects or embodiments, a surface of the floor channel, a surface of the cover, or both comprises an array of patterned nanostructures.

In some embodiments, a glass composition comprises: SiO₂ in a range of 56 mol. % to 72 mol. %; Al₂O₃ in a range of 5 mol. % to 22 mol. %; B₂O₃ in a range of 0 mol. % to 15 mol. %; Na₂O in a range of 3 mol. % to 25 mol. %; K₂O in a range of 0 mol. % to 5 mol. %; MgO in a range of 1 mol. % to 6 mol. %; SnO₂ in a range of 0 mol. % to 1 mol. %.

In one aspect, which is combinable with any of the other aspects or embodiments, the glass composition further comprises: Li₂O in a range of 0 mol. % to 7 mol. %; and P₂O₅ in a range of 0 mol. % to 10 mol. %.

In one aspect, which is combinable with any of the other aspects or embodiments, the glass composition further comprises: CaO in a range of 0 mol. % to 3 mol. %; and ZrO₂ in a range of 0 mol. % to 2 mol. %.

In one aspect, which is combinable with any of the other aspects or embodiments, the glass composition further comprises: ZnO in a range of 0 mol. % to 6 mol. %.

In one aspect, which is combinable with any of the other aspects or embodiments, the glass composition is configured to have a strength of at least 600 MPa.

In one aspect, which is combinable with any of the other aspects or embodiments, the glass composition is configured to have a refractive index of at least 1.50.

In some embodiments, a method of strengthening a glass composition comprises: replacing a first alkali metal cation having a first size with a second alkali metal cation having a second size, wherein the second size is greater than the first size, and wherein the glass composition is configured to have a strength in a range of 100 MPa and 200 MPa prior to the replacing and a strength of at least 600 MPa after replacing.

In one aspect, which is combinable with any of the other aspects or embodiments, the first alkali metal cation is at least one of a lithium cation or a sodium cation, and wherein the second alkali metal cation is at least one of a sodium cation or a potassium cation.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claimed subject matter. The accompanying drawings are included to provide a further understanding and are incorporated in and constitute a part of this specification. The drawings illustrate one or more embodiment(s), and together with the description, serve to explain principles and operation of the various embodiments.

### BRIEF DESCRIPTION OF THE DRAWINGS

FIGS. 1A to 1D depict a process flow for the manufacture of a microfluidic device, according to some embodiments.

FIG. 2 illustrates a plane view schematic drawing of a two-channeled microfluidic device, according to some embodiments.

FIG. 3 illustrates a cross-sectional schematic drawing along a channel direction of a flow cell, according to some embodiments.

FIG. 4 illustrates a cross-sectional schematic drawing along a channel direction of a one-sided patterned flow cell, according to some embodiments.

FIG. 5 illustrates a cross-sectional schematic drawing along a channel direction of a double-sided patterned flow cell, according to some embodiments.

FIG. 6 illustrates a Box and Whiskers plot of the minimum, maximum, average, and standard deviation of a cover glass surface tilt or slope, according to some embodiments.

FIGS. 7A and 7B illustrate autofluorescence of strengthened thin cover glass substrates, according to some embodiments.

FIG. 8 is a photo of a 156 mm² glass-based substrate wafer having fourteen individual channels disposed in the glass-based substrate, according to some embodiments.

FIGS. 9A to 9C illustrate data for two channels disposed in the glass-based substrate as showed in FIG. 8, as imaged using a laser interferometer, according to some embodiments. Specifically, FIG. 9A shows a false-colored image showing the depths of the two channels; FIG. 9B is a scatter plot of the channel floor surface tilt or slope for channel A in FIG. 9A; and FIG. 9C a Box and Whiskers plot of the minimum, maximum, average, and standard deviation of the channel floor surface tilt or slope.

FIG. 10 is a photo of the 156 mm² glass-based substrate wafer as in FIG. 8, with each channel floor surface having an array of patterned nanowells, according to some embodiments.

FIG. 11 illustrates a scanning electron microscopic (SEM) image of the array of patterned nanowells on one of the channel floor surfaces of the glass-based substrate showed in FIG. 10, according to some embodiments.

### DETAILED DESCRIPTION

Reference will now be made in detail to exemplary embodiments which are illustrated in the accompanying drawings. Whenever possible, the same reference numerals will be used throughout the drawings to refer to the same or like parts. The components in the drawings are not necessarily to scale, emphasis instead being placed upon illustrating the principles of the exemplary embodiments. It should be understood that the present application is not limited to the details or methodology set forth in the description or illustrated in the figures. It should also be understood that the terminology is for the purpose of description only and should not be regarded as limiting.

Additionally, any examples set forth in this specification are illustrative, but not limiting, and merely set forth some of the many possible embodiments of the claimed invention. Other suitable modifications and adaptations of the variety of conditions and parameters normally encountered in the field, and which would be apparent to those skilled in the art, are within the spirit and scope of the disclosure.

The term “surface roughness” means Ra surface roughness determined as described in ISO 25178, Geometric Product Specifications (GPS)—Surface texture: areal, filtered at 25 μm unless otherwise indicated. The surface roughness values reported herein were obtained using atomic force microscopy (AFM).

The present disclosure provides methods to make and use glass-based microfluidic devices having thin and strengthened cover glass structures for optical detection-based NGS or single molecule analysis.

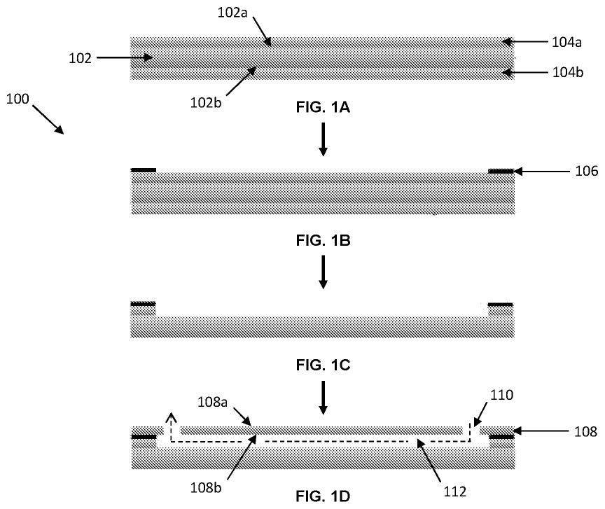

FIGS. 1A to 1D depict a process flow 100 for the manufacture of a microfluidic device according to some embodiments.

In a first step as shown in FIG. 1A, a three-layered substrate is provided comprising a core layer 102 interposed between a first cladding layer 104a and a second cladding layer 104b. The core layer 102, first cladding layer 104a, and second cladding layer 104b comprise, independently, glass-based materials (e.g., glass materials, glass-ceramic materials, ceramic materials, or combinations thereof). In some embodiments, the core layer 102 comprises a glass composition different from the glass composition of the first cladding layer 104a and the second cladding layer 104b. The first cladding layer 104a and the second cladding layer 104b may be formed from a first cladding glass composition and a second cladding glass composition, respectively. In some embodiments, the first cladding glass composition and the second cladding glass composition may be the same material. In other embodiments, the first cladding glass composition and the second cladding glass composition may be different materials.

FIG. 1A illustrates the core layer 102 having a first surface 102a and a second surface 102b opposed to the first surface 102a. A first cladding layer 104a is fused directly to the first surface 102a of the core layer 102 and a second cladding layer 104b is fused directly to the second surface 102b of the core layer 102. The glass cladding layers 104a and 104b may be fused to the core layer 102 without any additional materials, such as adhesives, polymer layers, coating layers or the like being disposed between the core layer 102 and the cladding layers 104a and 104b. Thus, in this instance, the first surface 102a of the core layer 102 is directly adjacent the first cladding layer 104a, and the second surface 102b of the core layer 102 is directly adjacent the second cladding layer 104b. In some embodiments, the core layer 102 and the glass cladding layers 104a and 104b are formed via a fusion lamination process (e.g., fusion draw process). Diffusive layers (not shown) may form between the core layer 102 and the cladding layer 104a, or between the core layer 102 and the cladding layer 104b, or both.

The first and second cladding layers may be formed from a composition comprising silicon dioxide (SiO₂) having a concentration in a range of 45 mol. % to 60 mol. %, alumina (Al₂O₃) having a concentration in a range of 8 mol. % to 19 mol. %, boron trioxide (B₂O₃) having a concentration in a range of 5 mol. % to 23 mol. %, and sodium oxide (Na₂O) having a concentration in a range of 3 mol. % to 21 mol. %. The cladding layers may be substantially free of arsenic (As) and cadmium (Cd) to provide that the degradation rate of the cladding layers is at least ten times greater than the degradation rate of the core layer when a high concentration acid (e.g., 10% hydrogen fluoride, HF) is used as an etchant, or at least twenty times greater than the degradation rate of the core layer when a low concentration acid (e.g., 1% or 0.1% HF solution) is used as an etchant.

The core layer may be formed from at least one of an alkaline earth boro-aluminosilicate glass (e.g., Corning Eagle XG®), Corning FotoForm® Glass, Corning Iris™ Glass, or Corning Gorilla® Glass. For example, the core layer may be formed from a glass having a composition of 79.3 wt. % SiO₂, 1.6 wt. % Na₂O, 3.3 wt. % K₂O, 0.9 wt. % KNO₃, 4.2 wt. % Al₂O₃, 1.0 wt. % ZnO, 0.0012 wt. % Au, 0.115 wt. % Ag, 0.015 wt. % CeO₂, 0.4 wt. % Sb₂O₃, and 9.4 wt. % Li₂O. In some embodiments, the core layer comprises at least one of Corning Eagle XG® Glass or Corning Iris™ Glass, for example, due to their ultra-low auto-fluorescence.

FIG. 1B illustrates a coating and patterning process whereby a glass-to-glass bonding material 106 (e.g., bonding layer) is deposited onto a surface of the first cladding layer 104a. For example, the glass-to-glass bonding material 106 comprises at least one of Cr/CrON, metals (e.g., Zn, Ti, Ce, Pb, Fe, Va, Cr, Mn, Mg, Ge, Au, Ni, Cu, Al, Ta, Nb, Sn, In, Co, W, Yb, Zr, etc.), metal oxides thereof (e.g., Al₂O₃, ZnO₂, Ta₂O₅, Nb₂O₅, SnO₂, MgO, indium tin oxide (ITO), CeO₂, CoO, Co₃O₄, Cr₂O₃, Fe₂O₃, Fe₃O₄, In₂O₃, Mn₂O₃, NiO, a-TiO₂ (anatase), r-TiO₂ (rutile), WO₃, Y₂O₃, ZrO₂), glues (e.g., UV-curable), tapes (e.g., double-sided pressure adhesive tape, double-sided polyimide tape), or polymer-carbon black composite films (e.g., polyimide-carbon black film).

Bonding material 106 of the composite structure of FIG. 1B may be formed using at least one of spin-coating, dip coating, chemical vapor deposition (CVD) (e.g., plasma-assisted, atomic layer deposition (ALD), vapor-phase epitaxy (VPE), etc.), physical vapor deposition (PVD) (e.g., sputter, evaporative, e-beam, etc.), laser-assisted deposition, etc.

FIG. 1C illustrates a wet chemical etching process whereby, after patterning the glass-to-glass bonding material 106 (as shown in FIG. 1B), the three-layered glass substrate is subject to selective chemical etching to remove the second cladding layer 104b and a portion of the first cladding layer 104a not protected by the patterned glass-to-glass bonding material 106 until the core glass layer 102 is exposed and its surface becomes one surface of a microfluidic channel (e.g., for the immobilization of biomolecules). In the wet chemical etching process, the patterned glass-to-glass bonding material 106 serves as an etch mask to prevent contacting the masked region of the first cladding layer 104a with the etchant. The first cladding layer 104a and the second cladding layer 104b may have an etch rate in the etchant that is higher than the etch rate of the core glass layer 102 such that the core glass layer 102 serves as an etch stop to control a depth of the microfluidic channel. In some embodiments, a polymeric layer is deposited on the glass-to-glass bonding material 106 prior to the wet chemical etching process.

Alternatively, an etchant resist polymer sheet may be formed on the etchant contact surface of the second cladding layer 104b and/or a region of the first cladding layer 104a containing the patterned glass-to-glass bonding material 106 prior to etching such that post-etching the second cladding layer 104b remains intact while the exposed region of the first cladding layer 104a is removed to form the channel.

Patterning of the glass-to-glass bonding material 106 may be conducted using either additive or subtractive patterning techniques (e.g., ink printing, tape bonding, vapor deposition, plasma etching, wet etching, etc.).

The wet etching chemical comprises a suitable component capable of degrading or dissolving the glass article. For example, the suitable wet etching chemical includes an acid (e.g., HCl, HNO₃, H₂SO₄, H₃PO₄, H₃BO₃, HBr, HClO₄, HF, acetic acid), a base (e.g., LiOH, NaOH, KOH, RbOH, CsOH, Ca(OH)₂, Sr(OH)₂, Ba(OH)₂), or a combination thereof.

FIG. 1D represents the final assembly of the microfluidic device after application of a glass cover 108 (having a first surface 108a and a second surface 108b) atop glass-to-glass bonding material 106. The glass cover 108 comprises a glass-based material (e.g., glass materials, glass-ceramic materials, ceramic materials, or combinations thereof).

In some examples, the cover has a thickness of at most 200 μm. In some examples, the cover has a thickness in a range of 10 μm and 200 μm, or in a range of 50 μm and 200 μm, or in a range of 75 μm and 200 μm, or in a range of 100 μm and 180 μm, or in a range of 125 μm and 160 μm, or in a range of 150 μm and 175 μm.

In some examples, the cover has a composition comprising silicon dioxide (SiO₂) having a concentration in a range of 56 mol. % to 72 mol. %; alumina (Al₂O₃) having a concentration in a range of 5 mol. % to 22 mol. %; boron trioxide (B₂O₃) having a concentration in a range of 0 mol. % to 15 mol. %; sodium oxide (Na₂O) having a concentration in a range of 3 mol. % to 25 mol. %; potassium oxide (K₂O) having a concentration in a range of 0 mol. % to 5 mol. %; magnesium oxide (MgO) having a concentration in a range of 1 mol. % to 6 mol. %; and tin oxide (SnO₂) having a concentration in a range of 0 mol. % to 1 mol. %.

In some examples, the cover may further comprise lithium oxide (Li₂O) having a concentration in a range of 0 mol. % to 7 mol. % and phosphorus pentoxide (P₂O₅) having a concentration in a range of 0 mol. % to 10 mol. %. In some examples, the cover may further comprise calcium oxide (CaO) having a concentration in a range of 0 mol. % to 3 mol. % and zirconium dioxide (ZrO₂) having a concentration in a range of 0 mol. % to 2 mol. %. In some examples, the cover may further comprise zinc oxide (ZnO) having a concentration in a range of 0 mol. % to 6 mol. %.

In some embodiments, a laser-assisted radiation bonding process was used to bond glass cover 108 with first cladding layer 104a using glass-to-glass bonding material 106. Without being bound by any particular theory or process, it is thought that the bonding of the glass-to-glass bonding material 106 to the first cladding layer 104a and glass cover 108, respectively, is the result of diffusing a portion of the glass-to-glass bonding material 106 into the first cladding layer 104a and into the glass cover 108 such that each portion of the first cladding layer 104a and the glass cover 108 comprising the diffused glass-to-glass bonding material 106 is the bonded volume layer (not shown). As oriented, the glass-to-glass bonding material 106 may not be transparent to the wavelength of the laser emission while the first cladding layer 104a and glass cover 108 may be transparent to the wavelength of the laser emission. In such embodiments, the laser emission may pass through the glass cover 108 and/or the three-layered substrate and be absorbed by the glass-to-glass bonding material 106. In some embodiments, the diffusion of the glass-to-glass bonding material 106 into the first cladding layer 104a and glass cover 108, respectively, renders the bonded volume layer transparent to the wavelength of the laser emission.

In some embodiments, the bonding of the glass-to-glass bonding material 106 to the first cladding layer 104a and glass cover 108, respectively, is accomplished using a laser which has a wavelength such that at least one of the substrates (e.g., first cladding layer 104a and/or glass cover 108) is transparent to that wavelength. An interface between the layers provides a change in the index of transmission or optical transmissivity which results in absorption of laser energy at the interface and localized heating to create a bond.

In some embodiments, where the glass-to-glass bonding material 106 is Cr/CrON, the Cr component may function as a heat absorption layer which is opaque or blocking to the laser wavelength and has an affinity for diffusion into the first cladding layer 104a and/or the glass cover 108. In alternative embodiments, other materials having appropriate wavelength absorption and diffusion affinity characteristics may be employed as the heat absorption layer. The thickness of the heat absorption layer may be as thick as desired to compensate for surface roughness or control timing and temperatures of the process.

Additionally, and/or alternatively, the bonding of the glass-to-glass bonding material 106 to the first cladding layer 104a and the glass cover 108 throughout the bonded volume layer can include melting at least one of the glass-to-glass bonding material 106, first cladding layer 104a, and/or glass cover 108 (e.g., localized melting at the site of laser emission absorption). Moreover, the bonding may also include fusing the glass-to-glass bonding material 106 to at least one of the first cladding layer 104a or glass cover 108. In some embodiments, the bonded volume layer is transparent to the wavelength of the laser emission.

In some embodiments, the bonding can be achieved via separate laser emission (not illustrated) as described in U.S. Pat. Nos. 9,492,990, 9,515,286, and/or 9,120,287, the entirety of which are incorporated herein by reference.

In other words, after the glass cover 108 is placed onto the etched structure of FIG. 1C (as described above) and is in close contact with the glass-to-glass bonding material 106, the combination is exposed to radiation (e.g., laser light treatment) to bond each of the first cladding layer 104a and the glass cover 108 to glass-to-glass bonding material 106 through bonded volume layers, respectively. Creating the structure of FIG. 1D may include positioning the cover substrate 108 on the glass-to-glass bonding material 106 and irradiating the bonding material 106 with electromagnetic radiation sufficient to diffuse at least a portion of the bonding material 106 into the cover substrate 108 and the first cladding layer 104a.

As a result, the second surface 108b of the glass cover 108 faces and is directly opposed to the first surface 102a of the core layer 102, with the second surface 108b being a ceiling surface of the microfluidic channel 112 and the first surface 102a being a floor surface. The ceiling surface 108b and floor surface 102a of the channel 112 may be highly parallel due to precision bonding and ultra-flatness of the channel surfaces. Controlled entry and exit of a fluid (e.g., test DNA samples) is conducted through holes 110 in the glass cover 108 extending from the first surface 108a to the second surface 108b (e.g., through-holes). The microfluidic channel 112 provides a flow path (dashed line) for the fluid through the microfluidic device. For example, when used for DNA sequencing, the microfluidic channel 112 provides a flow path for test DNA samples such that DNA fragments may be immobilized and partitioned onto the ceiling surface 108b and/or the floor surface 102a of the channel 112 to facilitate sequencing. The ceiling surface 108b and/or the floor surface 102a of the channel 112 may be treated, for example, chemically functionalized or physically structured (e.g., with nanowell arrays), to aid in performing a desired function (e.g., capture of desired fragments).

In some embodiments, although the substrate is described as a three-layered substrate (see FIG. 1A)), a two-layered substrate is also contemplated and comprises a core glass layer and a cladding layer, as described above. In this instance, the wet chemical etching process of FIG. 1C would result in removal of a portion of the cladding layer not protected by the patterned glass-to-glass bonding material until the core glass layer is exposed. Thus, in this instance, the glass-to-glass bonding material is patterned atop the cladding layer.

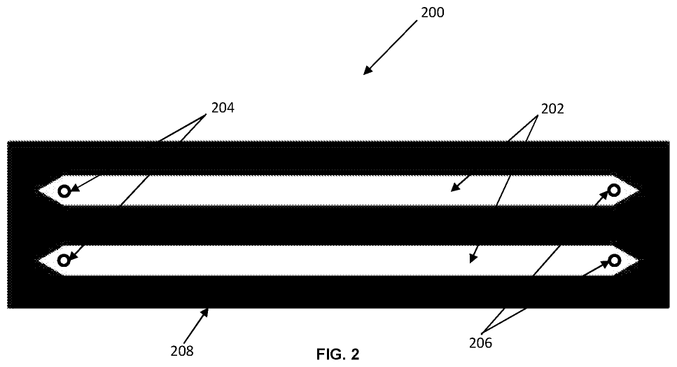

FIG. 2 is a plane view schematic drawing of a two-channeled microfluidic device 200 comprising a thin, strengthened, and substantially flat cover glass and fabricated by the methods disclosed herein, according to some embodiments. In this example, the microfluidic device 200 includes a microfluidic channel 202 as a flow path for test samples connecting an inlet 204 and an outlet 206 for controlled entry and exit, respectively. In other words, each of the inlet 204 and the outlet 206 are in fluid communication with the microfluidic channel 202. As described above, the microfluidic channel 202 has a floor surface being a surface of the core layer 102, a ceiling surface being a surface of the glass cover 108, and the first cladding layer 104a being at least a portion of the sidewalls of the microfluidic channel 202.

The microfluidic channel, inlet port, and outlet port may be made on the glass cover or the bottom substrate. In some examples, the inlet port and outlet port are formed on the bottom substrate, which is fabricated with glass, glass ceramics, silicon, pure silica, or other substrates.

The ceiling and floor surfaces of each channel 202 may be used for immobilizing biomolecules. Each individual channel may be separated with a bonding area 208 where the first cladding layer 104a and the glass cover 108 are bonded with the glass-to-glass bonding material 106, as described above. In other words, the bonding area 208 depicts the area where a hermetic seal is formed via the bonding layer. In some examples, the bonding layer may be formed by first patterning on the bottom substrate, followed by protection with photoresist or an etchant resistant polymer tape. After chemical etching, the photoresist protectant or polymer tape is removed to expose the bonding layer. In some examples, bonding the glass cover to the bottom substrate may also be achieved using a laser-assisted radiation bonding process.

In some examples, the cover has an average surface flatness of at most about 100 nm/mm, measured in a longitudinal direction at a central portion of the flow channel. In some examples, the cover has an average surface flatness in a range of 10 nm/mm and 90 nm/mm, or in a range of 20 nm/mm and 80 nm/mm, or in a range of 40 nm/mm and 60 nm/mm, measured in a longitudinal direction at a central portion of the flow channel. In some examples, the cover has an average surface flatness of at most about 75 nm/mm, or at most about 50 nm/mm, or at most about 25 nm/mm, measured in a longitudinal direction at a central portion of the flow channel.

The surface flatness can be measured using a laser interferometer (e.g., Zygo New View 3000, Zygo Z-mapper, Tropel FlatMaster), which measure differences in shape and tilt between a test sample surface and reference surfaces of the interferometer. For etched channels, the flatness of the microfluidic channel floor surface is measured relative to a top surface of the glass-to-glass bonding material 106 or a reference substrate when the test sample is placed against the reference substrate. For bonded microfluidic devices or flow cells, the flatness of the microfluidic channel floor surface is measured relative to a surface of the reference substrate, such that the device or flow cell is placed atop the reference substrate.

In some examples, the cover has a surface roughness of at most about 10 nm/μm². In some examples, the cover has a surface roughness in a range of 1 nm/μm² and 9 nm/μm², or in a range of 2 nm/μm² and 8 nm/μm², or in a range of 3 nm/μm² and 7 nm/μm². In some examples, the cover has a surface roughness of at most about 7.5 nm/μm², or at most about 5 nm/μm², at most about 2.5 nm/μm². The surface roughness can be measured using atomic force microscopy (AFM), which uses force between a probe (e.g., a pyramidal-shaped tip) and the sample to measure the topological features of a surface including surface roughness.

In some embodiments, a microfluidic device may contain a thin, strengthened, and substantially flat cover glass with a bottom substrate being a three-layered glass comprising a core layer sandwiched between two clad layers and having a pre-etched channel whose channel floor surface is also substantially flat. Since the core layer has a different composition and a much lower etching rate to an etchant than the cladding layers, the core layer may act as an etch stop layer, resulting in the channel floor surface that is substantially flat. In some examples, the flatness within the central region of the channel floor surface is less than 100 nm/mm, or less than 75 nm/mm, or less than 50 nm/mm, or less than 25 nm/mm.

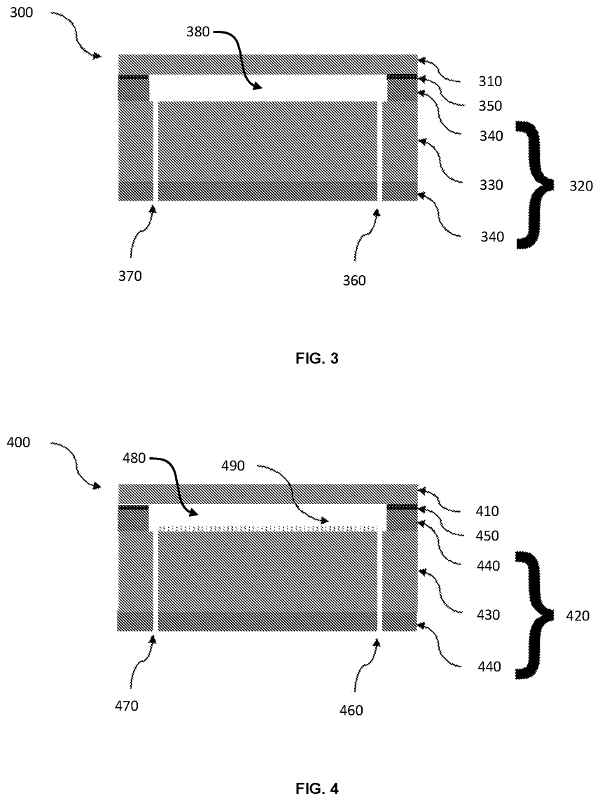

For example, FIG. 3 illustrates a cross-sectional schematic drawing along a channel direction of a flow cell, according to some embodiments. In particular, the non-patterned microfluidic device 300 comprises a thin, strengthened and substantially flat cover glass 310 and a three-layered bottom glass substrate 320 having a core layer 330 sandwiched between two clad layers 340. The bottom substrate 320 contains a pre-etched channel 380 on the side facing the cover glass 310, with end surfaces of the channel side wall having a bonding layer 350 formed thereon. In some examples, the bonding layer 350 may be a metal or a polymer-carbon black composite film or a glue or a tape. The bottom substrate 320 also includes an inlet port 360 and an outlet port 370. The inlet port is connected to an external solution, and is used to introduce the solution into the microfluidic channel 380, while the outlet port is connected to an external waste container, and is used to exit the solution out of the microfluidic channel 380.

In some examples, a surface of the floor channel, a surface of the cover, or both comprises an array of patterned nanostructures.

FIG. 4 illustrates a cross-sectional schematic drawing along a channel direction of a one-sided patterned flow cell, according to some embodiments. In particular, the one-sided patterned microfluidic device 400 comprises a thin, strengthened and substantially flat cover glass 410. Elements 410-480 of FIG. 4 are analogous to elements 310-380 as described above for FIG. 3. The bottom glass substrate 420 comprises a pre-etched channel 480 whose channel floor surface may be modified by chemical or physical means to form nanopatterned features 490. In some examples, the nanopatterned features may be deposited chemical moieties. In some examples, the nanopatterned features may be a predetermined surface roughness. In some examples, the nanopatterned features (e.g., nanowells) may be formed with lithographic techniques that are capable of nanopatterning inside pre-etched, deep channels (e.g., photolithography, nanoimprinting, nanosphere lithography, etc.).

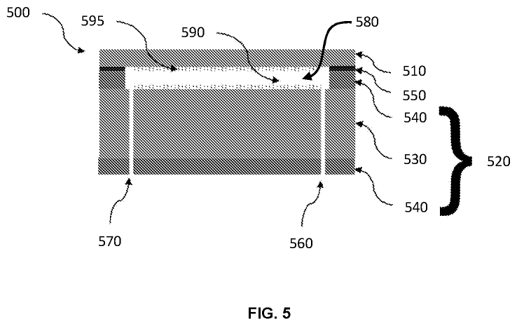

FIG. 5 illustrates a cross-sectional schematic drawing along a channel direction of a double-sided patterned flow cell, according to some embodiments. In particular, the double-sided patterned microfluidic device 500 comprises a thin, strengthened and substantially flat cover glass 510. Elements 510-580 of FIG. 5 are analogous to elements 310-380 as described above for FIG. 3. The bottom glass substrate 520 comprises a pre-etched channel 580 whose channel floor surface may be modified by chemical or physical means to form nanopatterned features 590. Moreover, the cover glass 510, whose bottom surface may function as the channel 580 ceiling, may also be modified by similar means (as described above for FIG. 4) to form nanopatterned features 595.

Using strengthened glass allows for direct perform patterning on flat, thin glass using a variety of lithographic techniques including photolithography, nanoimprinting and nanosphere lithography. Nanopatterning typically can only be done for thick glass substrates (e.g., 0.7 mm and 0.5 mm). For thin glass which is highly fragile and extremely difficult to handle without damaging (e.g., 0.3 mm, or in particular, about 0.15 mm), a carrier is usually needed, which adds cost and complexity of the nanopatterning process.

Individual microfluidic devices can be finally prepared by laser cutting (e.g., CO₂, IRIS laser) in an ablation process. In some examples, the microfluidic device is a flow cell for DNA sequencing.

### EXAMPLES

The embodiments described herein will be further clarified by the following examples.

### Example 1—Glass Compositions

The glass compositions of Table 1 may be used as the thin, strengthened, and substantially flat cover glass of the microfluidic devices disclosed herein.

TABLE 1

| Family | 1 (mol. %) | 2 (mol. %) | 3 (mol. %) |
|---|---|---|---|
| SiO₂ | 64-66 | 56-72 | 66-74 |
| Al₂O₃ | 9.39-15 | 5-18 | 9-22 |
| B₂O₃ | 0-9.0 | 0-15 | 3-4.5 |
| Li₂O | 0-5 | 0-7 | — |
| Na₂O | 6-15 | 3-25 | 9-20 |
| K₂O | 0-4 | 0-5 | 0-5 |
| MgO | 1-3 | 1-6 | 1-6 |
| CaO | 0-3 | — | 0-2 |
| ZrO₂ | 0-2 | — | 0-2 |
| P₂O₅ | 0-5 | 0-10 | — |
| ZnO | — | — | 0-6 |
| SnO₂ | 0-1 | 0-1 | 0-1 |

The glass families of Table 1 may be made using fusion draw processes to enable better scratch resistance, which is an important attribute for microfluidic devices used for optical imaging of biomolecular interactions, as compared with currently available glass such as soda lime glass or biophotonic glass (e.g., D263T or D236M). The glass families shown in Table 1 may be strengthened using an ion exchange process, which results in a substantial improvement of glass strengthening properties to enhance damage resistance by, for example, sharp impact or indentation. Alkali and alkaline-earth cations as network modifiers may form non-bridging oxygens (i.e., oxygens bonded to only one silicon atom), which reduces damage resistance of the glass to abrasion, scratching, or the like. During the ion exchange process, cations, such as monovalent alkali metal cations (e.g., Li, Na, etc.) which are present in the glass families of Table 1, are replaced with larger cations, such as larger monovalent alkali metal cations (e.g., Na, K, etc.). This replacement of ions causes the surface of the glass to be in a state of compression and the core in compensating tension, increasing the surface compression from about 100 MPa to above 600 MPa, which results in the glass having higher damage resistance.

Using the ion exchange process, the Depth of Layer (DOL) for glasses described in Table 1 was determined to be in the range of 35 μm to 45 μm with 100% KNO₃ hot salt bath. Depth of Layer measures the compressive strength of glass specific to chemically strengthened glass. It is the depth into the surface of the glass to which compressive stress may be introduced and is defined as the distance from the physical surface to the zero stress point internal to the glass. Depth of Layer may be controlled by glass composition and ion exchange recipe (e.g., time, temperature, and cycle of the salt bath). In some examples, the temperature of the molten salt bath is in a range of 380° C. to 450° C. In some examples, the immersion times are in a range of 2 hrs to 16 hrs.

Glasses of compositions as in Table 1 by fusion draw processes of FIGS. 1A-1D may have a strength in a range of 100 MPa to 200 MPa prior to ion exchange. After ion exchange, the glass compositions may have enhanced strengths exceeding 600 MPa. Furthermore, the average surface flatness of the glass compositions in Table 1 was in a range of 10 nm/mm to 50 nm/mm both before and after ion exchange was conducted.

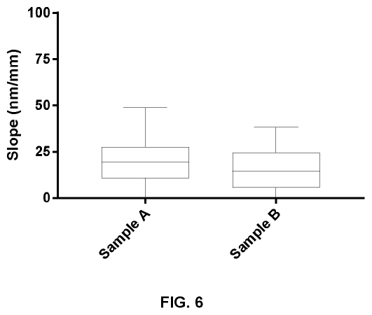

For example, FIG. 6 illustrates a Box and Whiskers plot of the minimum, maximum, average, and standard deviation of a cover glass surface tilt or slope for two 170 μm thick cover glass wafer samples (area of about 156 mm²) according to Table 1, as measured using a Tropel® FlatMaster® laser interferometer to measure flatness. The slope, which was calculated as the derivative (i.e., the first order fit) of flatness data, shows that the tilt or slope for both samples is very small (less than 50 nm/mm), suggesting that the thin cover glass is very flat.

Transmittance of light having wavelengths in a range of 350 nm to 2250 nm for each of glasses was greater than 90% both before and after ion exchange. Moreover, cover glasses prepared with glass compositions as in Table 1 had a refractive index of 1.50 before ion exchange, but 1.51 for the surface compression level after ion exchange, thereby resulting in better imaging quality when being used for optical imaging. The coefficient of thermal expansion (CTE) for the glasses in Table 1 was in a range of 75×10⁻⁷/° C. to 82×10⁻⁷/° C.

### Example 2—Autofluorescence Characterization

Autofluorescence measurements were conducted using excitation wavelengths in a range of 450 nm to 750 nm using glass covers having compositions of Table 2 in a confocal fluorescence scanner. The scanner can image the entire surface of a typical glass slide (1 inch×3 inches). Aside from autofluorescence uniformity across the entire surface, the averaged autofluorescence level may also be calculated.

TABLE 2

| Family | A (mol. %) | B (mol. %) | C (mol. %) |
|---|---|---|---|
| SiO₂ | 65.78 | 64.96 | 61.85 |
| Al₂O₃ | 13.75 | 16.42 | 19.68 |
| B₂O₃ | 0 | 0 | 3.90 |
| Na₂O | 13.67 | 14.77 | 12.91 |
| MgO | 4.11 | 3.39 | 1.43 |
| SnO₂ | 0.46 | 0.40 | 0.22 |

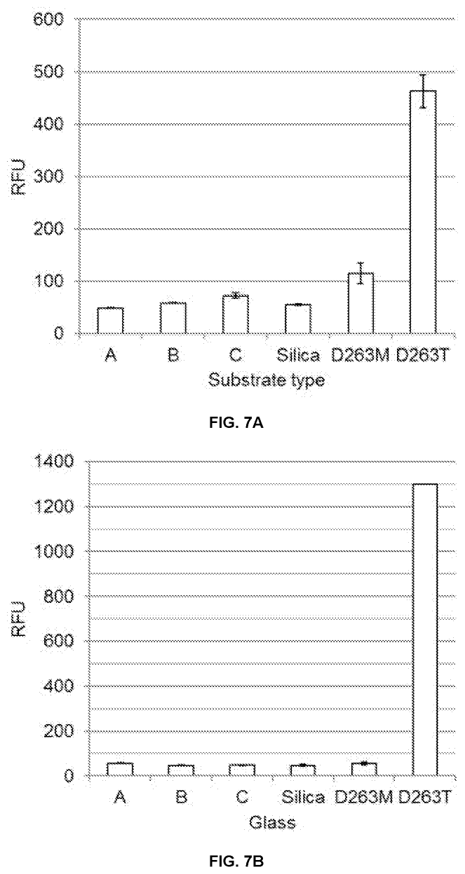

FIGS. 7A and 7B illustrate autofluorescence of strengthened thin cover glass substrates, according to some embodiments, in comparison with other glass slides. In particular, FIGS. 7A and 7B shows the autofluorescence of glass covers having compositions of families A, B, and C when using an excitation wavelength of 550 nm (with a measured emission wavelength of 570 nm) and an excitation wavelength of 650 nm (with a measured emission wavelength of 670 nm), respectively. Results showed that each glass cover had an autofluorescence signal similar or comparable to pure silica substrate, but much lower than other widely used biophotonics glasses such as D263T and D263M, both from Schott AG®. Pure silica is often viewed as a substrate displaying the lowest autofluorescence possible. In some examples, the autofluorescence of families A-C may be at most 100 RFU, or at most 90 RFU, or at most 80 RFU, or at most 70 RFU, or at most 60 RFU, or at most 50 RFU.

### Example 3—Flatness of Etched Channel in Three-Layered, Glass-Based Substrates

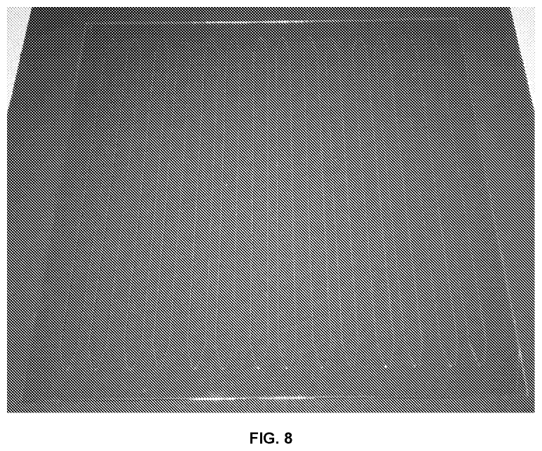

A 156 mm² three-layered glass wafer was patterned using inkjet printing of resist materials, with the wafer backside being protected using HF resistant polymer tape. After etching with a 10% HF solution at 35° C. for about 70 min, the exposed top cladding layer is selectively etched away to form channels in the glass substrate, followed by peel-off of the tape and sonication for resist removal. The glass wafers have two cladding layers having a thickness of 0.11 mm, and a core layer having a thickness of 0.8 mm. FIG. 8 shows a photo of a 156 mm² three-layered glass wafer containing fourteen etched channels, each channel having a length of 135 mm, a width of 5 mm, and a depth of 110 μm. A Tropel® FlatMaster® laser interferometer was then used to examine the depth and floor surface flatness of the channels made in the glass substrate.

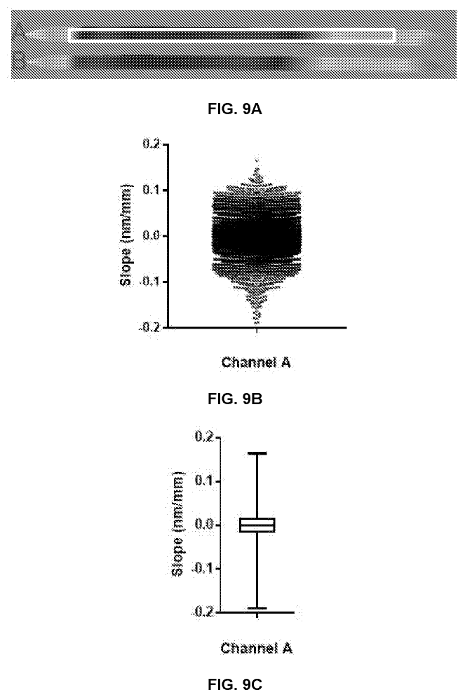

FIGS. 9A to 9C illustrate depth and floor surface flatness data for two channels disposed in the glass-based substrate as showed in FIG. 8, as imaged using a laser interferometer. Specifically, FIG. 9A shows a false-colored image showing the depths of the two channels; FIG. 9B is a scatter plot of the channel floor surface tilt or slope for channel A in FIG. 9A; and FIG. 9C a Box and Whiskers plot of the minimum, maximum, average, and standard deviation of the channel floor surface tilt or slope. Results in FIG. 9A show that both channels A and B have a relatively uniform depth of about 110 μm±2.5 μm, as defined by the thickness of the cladding layer. FIGS. 9B and 9C indicate that the tilt or slope of the channel floor surface is small—below 50 nm/mm—suggesting that the channel floor surfaces are flat.

### Example 4—Nanopatterning Channels

After characterizing for depth and floor surface flatness, the 156 mm² three-layered glass wafer of FIG. 8 was patterned to form an array of patterned nanostructures. Initially, a top surface of the wafer was protected with a vinyl polymer tape, leaving the channels open and unprotected. Then, a tightly close packed monolayer of 600 nm polystyrene beads was transferred onto the wafer using a Langmuir-Blodgett device, such that the channel floor surface was coated with the bead monolayer, after which point the polymer tape was removed. Thereafter, the wafer having the monolayer of beads on the channel floor surfaces was exposed to oxygen plasma to reduce bead size to about 260 nm and a 50 nm Al₂O₃ layer was deposited thereon using e-beam deposition. Finally, all beads were stripped using sonication in water bath to form an array of nanowells with well-defined size, geometry and depth on the channel floor surfaces.

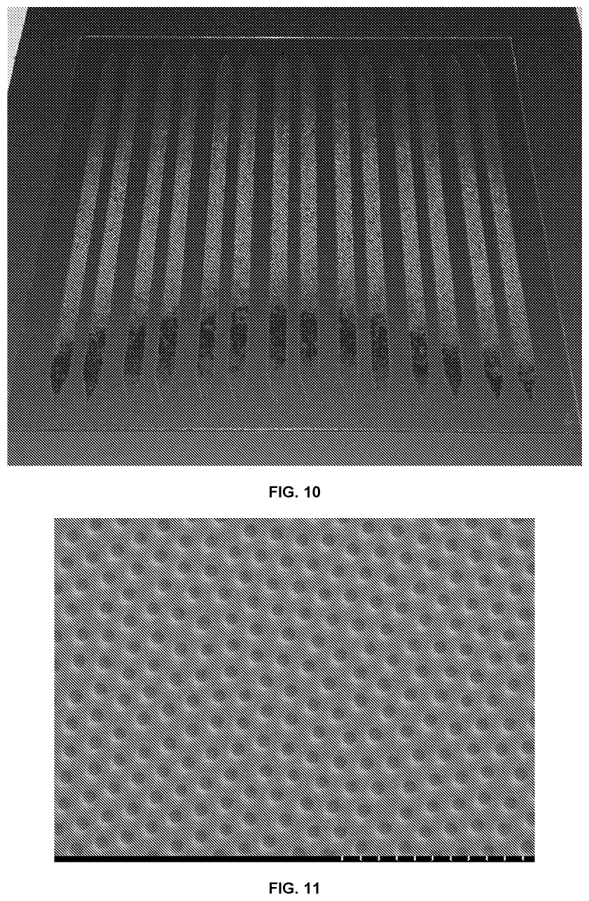

FIG. 10 is a photo of the 156 mm² glass-based substrate wafer as in FIG. 8, with each channel floor surface having an array of patterned nanowells, according to some embodiments. The angled photo is obtained as the wafer is illuminated with a strong white light, which reveals an interference pattern arising from long-range ordering of nanowells on the channel floor surfaces.

FIG. 11 illustrates a scanning electron microscopic (SEM) image of the array of patterned nanowells on one of the channel floor surfaces of the glass-based substrate showed in FIG. 10. The nanowell side wall is made of Al₂O₃, while the bottom is a core layer surface. The nanowells have an averaged circular diameter of about 256±8 nm, and an averaged pitch between adjacent wells of about 608±30 nm. Atomic force microscopy (AFM) data (not shown) indicates a depth of the nanowells to be about 50 nm, as determined by the Al₂O₃ deposition.

Combined with thin, strengthened, and substantially flat cover glass structures (described above), the ultra-flat channel floor surface (formed by the three-layered glass substrate, described above) and the patterning (formed by nanosphere lithography, described above) enable a high-quality microfluidic device allowing for high-quality biomolecular analysis using optical imaging systems.

Thus, as presented herein, a glass composition and method of fabrication of glass-based microfluidic devices are provided to form microfluidic devices having thin and strengthened cover glass structures as well as low autofluorescence for optical detection-based NGS or single molecule analysis.

Due to the thin, strengthened and substantially flat cover glass having a low autofluorescence, the device may (1) have high signal-to-noise detection of biomolecules on the channel surface; (2) allow for higher quality optical fluorescence imaging (e.g., with faster scanning and focusing speeds), thereby accelerating sequencing speed; and (3) enable high-dimensional stability, in particular under high temperature, to reduce incidents of damage related to handling, processing, assembly, packaging, nanopatterning, shipping, and/or scratching. Furthermore, the microfluidic devices disclosed therein comprise a bottom glass substrate having an etched channel that has a substantially flat channel floor surface, thereby allowing for fast scanning and imaging both the top and bottom surfaces of the channel and increasing the throughput of such devices for sequencing. Finally, the manufacturing methods disclosed herein are scalable, flexible, and provide for high throughput. Wafer level processing and assembly of microfluidic devices are possible.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

As utilized herein, “optional,” “optionally,” or the like are intended to mean that the subsequently described event or circumstance can or cannot occur, and that the description includes instances where the event or circumstance occurs and instances where it does not occur. The indefinite article “a” or “an” and its corresponding definite article “the” as used herein means at least one, or one or more, unless specified otherwise.

References herein to the positions of elements (e.g., “top,” “bottom,” “above,” “below,” etc.) are merely used to describe the orientation of various elements in the FIGURES. It should be noted that the orientation of various elements may differ according to other exemplary embodiments, and that such variations are intended to be encompassed by the present disclosure.

With respect to the use of substantially any plural and/or singular terms herein, those having skill in the art can translate from the plural to the singular and/or from the singular to the plural as is appropriate to the context and/or application. The various singular/plural permutations may be expressly set forth herein for the sake of clarity.

It will be apparent to those skilled in the art that various modifications and variations can be made without departing from the spirit or scope of the claimed subject matter. Accordingly, the claimed subject matter is not to be restricted except in light of the attached claims and their equivalents.

What is claimed is:

1. A microfluidic device comprising:
a flow channel disposed in a glass-based substrate; and
a cover bonded to the glass-based substrate and at least partially covering the flow channel,
wherein the cover has a thickness of at most 200 μm.

2. The microfluidic device of claim 1, further comprising:
an inlet opening through at least one of the glass-based substrate or the cover and in fluid communication with the flow channel; and
an outlet opening through at least one of the glass-based substrate or the cover and in fluid communication with the flow channel.

3. The microfluidic device of claim 1, wherein:
a first glass-based layer defines a floor of the flow channel;
a second glass-based layer defines sidewalls of the flow channel; and
the cover defines a ceiling of the flow channel.

4. The microfluidic device of claim 1, wherein the cover has a thickness in a range of 100 μm to 180 μm.

5. The microfluidic device of claim 1, wherein the cover comprises:
SiO2 in a range of 56 mol. % to 72 mol. %;
Al2O3 in a range of 5 mol. % to 22 mol. %;
B2O3 in a range of 0 mol. % to 15 mol. %;
Na2O in a range of 3 mol. % to 25 mol. %;
K2O in a range of 0 mol. % to 5 mol. %;
MgO in a range of 1 mol. % to 6 mol. %;
SnO2 in a range of 0 mol. % to 1 mol. %.

6. The microfluidic device of claim 5, wherein the cover further comprises:
Li2O in a range of 0 mol. % to 7 mol. %; and
P2O5 in a range of 0 mol. % to 10 mol. %.

7. The microfluidic device of claim 5, wherein the cover further comprises:
CaO in a range of 0 mol. % to 3 mol. %; and
ZrO2 in a range of 0 mol. % to 2 mol. %.

8. The microfluidic device of claim 7, wherein the cover further comprises:
ZnO in a range of 0 mol. % to 6 mol. %.

9. The microfluidic device of claim 1, wherein the cover is configured to have an autofluorescence in a wavelength range of 400 nm to 750 nm of as low as the autofluorescence of pure silica substrate.

10. The microfluidic device of claim 1, wherein the cover is configured to have an average surface tilt or slope of at most about 100 nm/mm, measured using a laser interferometer.

11. (canceled)

12. The microfluidic device of claim 1, wherein the cover is configured to have a surface roughness of at most about 10 nm/um2.

13. The microfluidic device of claim 12, wherein the surface roughness is at most about 5 nm/um2.

14. The microfluidic device of claim 1, wherein the cover is bonded to the glass-based substrate at a bonded volume comprising a bonding material diffused into each of the glass-based substrate and the cover.

15. The microfluidic device of claim 1, comprising a bonding layer disposed between the glass-based substrate and the cover.

16. The microfluidic device of claim 15, wherein the bonding layer comprises a metal including at least one of: gold, chromium, titanium, nickel, copper, zinc, cerium, lead, iron, vanadium, manganese, magnesium, germanium, aluminum, tantalum, niobium, tin, indium, cobalt, tungsten, ytterbium, zirconium, or an oxide thereof, or a combination thereof.

17. (canceled)

18. The microfluidic device of claim 15, wherein the bonding layer comprises a polymer-carbon black composite film.

19. The microfluidic device of claim 1, wherein the microfluidic device is a flow cell for DNA sequencing.

20. The microfluidic device of claim 1, wherein a surface of the floor channel, a surface of the cover, or both comprises an array of patterned nanostructures.

21. A glass composition, comprising:
SiO2 in a range of 56 mol. % to 72 mol. %;
Al2O3 in a range of 5 mol. % to 22 mol. %;
B2O3 in a range of 0 mol. % to 15 mol. %;
Na2O in a range of 3 mol. % to 25 mol. %;
K2O in a range of 0 mol. % to 5 mol. %;
MgO in a range of 1 mol. % to 6 mol. %;
SnO2 in a range of 0 mol. % to 1 mol. %.

22-26. (canceled)

27. A method of strengthening the glass composition of claim 21, comprising:
replacing a first alkali metal cation having a first size with a second alkali metal cation having a second size,
wherein the second size is greater than the first size, and
wherein the glass composition is configured to have a strength in a range of 100 MPa and 200 MPa prior to the replacing and a strength of at least 600 MPa after replacing.

28. (canceled)
